(19) United States
(12) Patent Application Publication
(10) Pub. No.: US 2012/0139098 A1
(43) Pub. Date: Jun. 7, 2012

(54) POWER PACKAGE MODULE

(75) Inventors: Kwan Ho LEE, Seoul (KR); Seog Moon CHOI, Seoul (KR)

(73) Assignee: SAMSUNG ELECTRO-MECHANICS CO., LTD., Gyunggi-do (KR)

(21) Appl. No.: 13/009,812

(22) Filed: Jan. 19, 2011

(30) Foreign Application Priority Data
Dec. 7, 2010 (KR) 10-2010-0124355

(51) Int. Cl. H01L 23/36

(52) U.S. Cl. 257/713; 257/E23.101

(57) ABSTRACT

Disclosed herein is a power package module, including: a power package mounted with a plurality of semiconductor chips; a heat radiation module coming into contact with the power package and including a first heat radiation member for discharging heat generated from the power package; and a second heat radiation member, one side of which is connected to the first heat radiation member and the other side of which is connected to the power package.

### CROSS REFERENCE TO RELATED APPLICATION

This application claims the benefit of Korean Patent Application No. 10-2010-0124355, filed Dec. 7, 2010, entitled “Power package module”, which is hereby incorporated by reference in its entirety into this application.

### BACKGROUND OF THE INVENTION

1. Technical Field

The present invention relates to a power package module.

2. Description of the Related Art

In a power package in which a plurality of semiconductor chips are mounted on a circuit substrate, a heat spread for dissipating heat and a heat sink for radiating heat are generally used in order to discharge the high heat generated from the semiconductor chips.

FIG. 1 is a perspective view showing a conventional power package. As shown in FIG. 1, in order to rapidly dissipate the high heat generated from a power package 10, generally, a heat radiation member, such as a heat spread (not shown) made of a metal having high thermal conductivity, is connected to the lower portion of a semiconductor chip.

Subsequently, in order to rapidly radiate the heat dissipated by the heat spread, a heat sink 20 is connected to the power package 10.

In this case, in order to decrease the thermal resistance at a site where the heat spread and the heat sink 20 come into contact with each other, thermal grease is applied onto the contact site, and the heat spread and the heat sink 20 are mechanically coupled with each other using a screw (not shown), thus finally combining the power package 10 with the heat sink 20.

However, such a method is problematic in that the performance of the thermal grease applied to the contact site of the heat spread and the heat sink 20 deteriorates with the passage of time, thus decreasing the radiation performance of the power package 10.

Further, since the worker changes the amount of the thermal grease that is applied, there is a problem in that constant radiation performance cannot be achieved with respect to each power package 10.

Furthermore, there are problems in that the heat sink 20 and the power package 20 are mechanically coupled with each other using a screw to increase the volume of the heat sink 20, and in that, when the heat sink 20 or the power package 10 becomes defective, it is difficult to separate the heat sink 20 and the power package from each other and to assemble the heat sink 20 and the power package.

In particular, since the heat sink 20 is coupled with a circuit substrate (not shown) of the power package 10 by a screw, there is a problem in that the circuit substrate is damaged during a manufacturing process.

### SUMMARY OF THE INVENTION

Accordingly, the present invention has been devised to solve the above-mentioned problems, and the present invention intends to provide a power package module including a power package and a heat radiation module connected with the power package to effectively radiate the high heat generated from the power package, thereby improving the reliability of a product and decreasing the volume of the power package module.

An aspect of the present invention provides a power package module, including: a power package mounted with a plurality of semiconductor chips; a heat radiation module coming into contact with the power package and including a first heat radiation member for discharging heat generated from the power package; and a second heat radiation member, one side of which is connected to the first heat radiation member and the other side of which is connected to the power package.

Here, the heat radiation module may further include a contact plate assembly disposed underneath the first heat radiation member and coming into contact with the power package.

Further, the contact plate assembly may include: an upper contact plate coming into contact with an upper portion of the power package; a lower contact plate coming into contact with a lower portion of the power package, in which the upper contact plate and the lower contact plate accommodate the power package therebetween; and a plate connector connecting the upper contact plate to the lower contact plate and preventing the power package from becoming detached from the contact plate assembly.

Further, the upper contact plate may include a stopper disposed at one end thereof and fixing the power package to prevent the upper contact plate from becoming detached from the power package.

Further, the lower contact plate may include a guide rail for slide-coupling the power package with the lower contact plate and a heat spread for dissipating heat generated from the power package.

Further, the power package may include: a circuit substrate mounted with a plurality of insulated gate bipolar transistors (IGBTs) and a drive IC; and a heat spread connected to a lower portion of the circuit substrate and dissipating the heat generated from the power package, wherein the heat spread may be provided with an insert hole having a diameter corresponding to a diameter of the second heat radiation member to connect the second heat radiation member to the power package through the insert hole.

Further, the power package may further include: a fixing groove formed in a side of the power package corresponding to the stopper such that the stopper is inserted into the fixing groove.

Further, the power package may further include: a guide groove formed in a side of the power package corresponding to the guide rail such that the power package slides along the guide rail of the lower contact plate.

Further, the first heat radiation member may be a heat sink including a plurality of radiation fins for directing heat to the outside.

Further, each of the plurality of radiation fins of the first heat radiation member may be provided with a through-hole having a diameter corresponding to the diameter of the second heat radiation member such that the second heat radiation member is connected to the first heat radiation member by the through-hole.

Further, the second heat radiation member may be a L-shaped heat pipe having bent portions such that one side thereof is connected to the first heat radiation member by the through-hole, and the other side thereof is connected to the power package through

[symbol]

### BRIEF DESCRIPTION OF THE DRAWINGS

The above and other objects, features and advantages of the present invention will be more clearly understood from the following detailed description taken in conjunction with the accompanying drawings, in which:

FIG. 1 is a perspective view showing a conventional power package;

FIG. 2 is an exploded perspective view showing a power package module according to an embodiment of the present invention;

FIG. 3 is a perspective view showing a power package according to an embodiment of the present invention;

FIG. 4 is a perspective view showing a power package according to another embodiment of the present invention;

FIG. 5 is an assembled perspective view showing a power package module according to an embodiment of the present invention; and

FIG. 6 is an assembled perspective view showing a power package module according to another embodiment of the present invention.

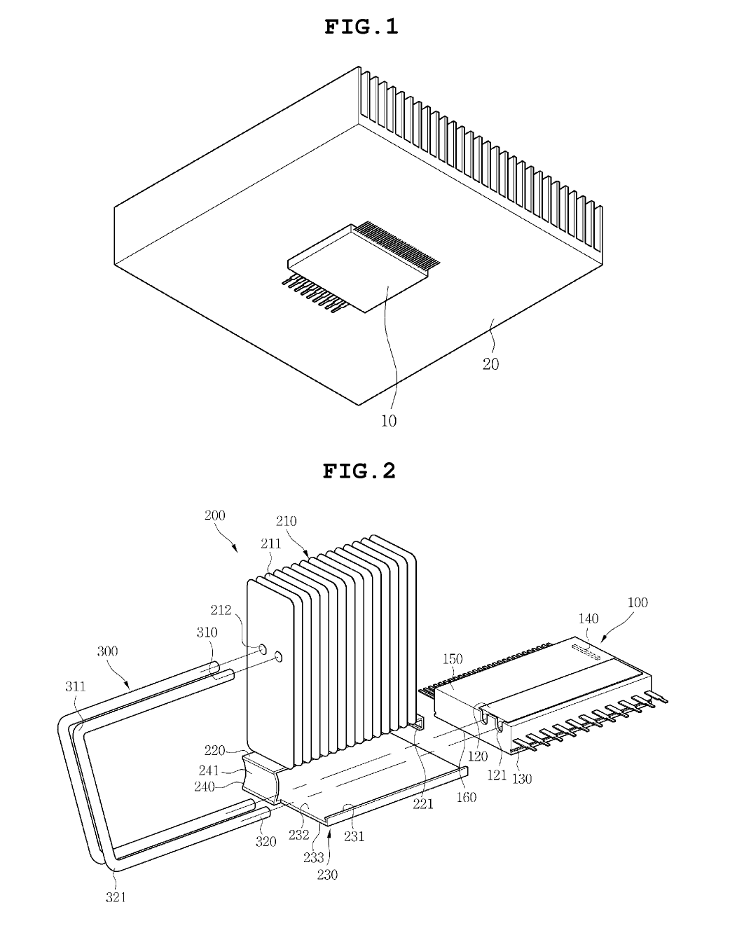

### DESCRIPTION OF THE PREFERRED EMBODIMENTS

The objects, features and advantages of the present invention will be more clearly understood from the following detailed description of the preferred embodiments taken in conjunction with the accompanying drawings. The same reference numerals are used throughout the accompanying drawings to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

FIG. 2 is an exploded perspective view showing a power package module according to an embodiment of the present invention. As shown in FIG. 2, the power package module includes a power package 100, a heat radiation module 200 including a first heat radiation member 210, and a second heat radiation member 300.

As shown in FIG. 2, the heat radiation module 200 comes into contact with the power package 100, and includes a first heat radiation member 210 for discharging the high heat generated from the power package 100 to the outside. Further, the heat radiation module 200 may further include a contact plate assembly disposed underneath the first heat radiation member 210 and coming into contact with the power package 100.

More concretely, the contact plate assembly includes an upper contact plate 220 accommodating the power package 100 and coming into contact with the upper portion 150 of the power package 100, a lower contact plate 230 coming into contact with the lower portion 160 of the power package 100, and a plate connector 240 connecting the upper contact plate 220 and the lower contact plate 230 to each other and preventing the power package 100 from becoming detached from the contact plate assembly.

Further, the upper contact plate 220, the lower contact plate 230 and the plate connector 240, which constitute the contact plate assembly, may be made of a metal material having elasticity in order that they may be easily opened in the form of a clip to couple them with the power package 100.

In particular, the plate connector 240 may be formed to have a curved shape because the upper contact plate 220 and the lower contact plate 230 must be coercively opened by external force during the manufacturing process.

As such, since the power package 100 and the heat radiation module 200 can be easily attached and detached to/from each other, the manufacturing process can be simplified compared to the above-mentioned conventional manufacturing process in which thermal grease is applied and the heat spread and the heat sink are mechanically coupled with each other using a screw, so that the productivity of products can be improved.

Further, when the power package 100 or the heat radiation module 200 becomes defective, defective products can be easily replaced even after the manufacturing process or the production of products.

Further, the upper contact plate 220 may be provided with a stopper 221 for fixing the power package 100 at the end thereof located in a direction opposite to the plate connector 240 in order to prevent the power package 100 attached to the upper contact plate 220 from becoming detached therefrom.

Meanwhile, the lower contact plate 230 may be provided with a guide rail 231 at the lateral side thereof so that it may be smoothly coupled with the power package 100.

Further, the lower contact plate 230 may be provided with a heat spread (not shown) at one side 232 coming into contact with the lower portion 160 of the power package 100 or the other side 233 opposite to the one side 232 in order to dissipate the high heat generated from the power package.

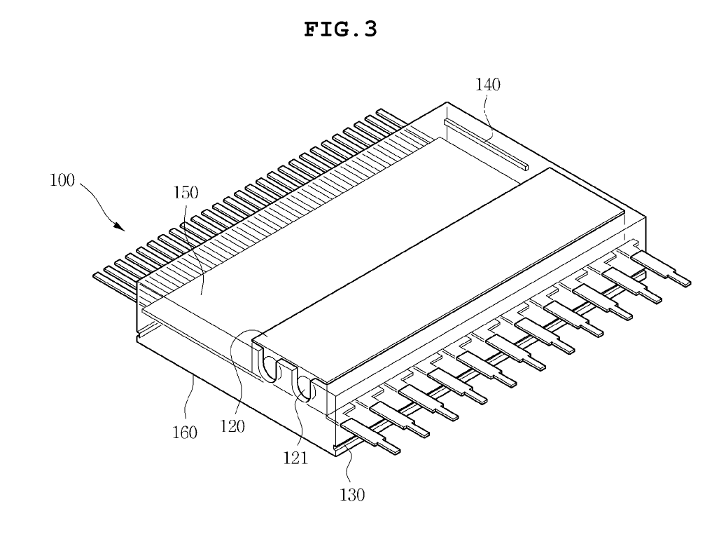

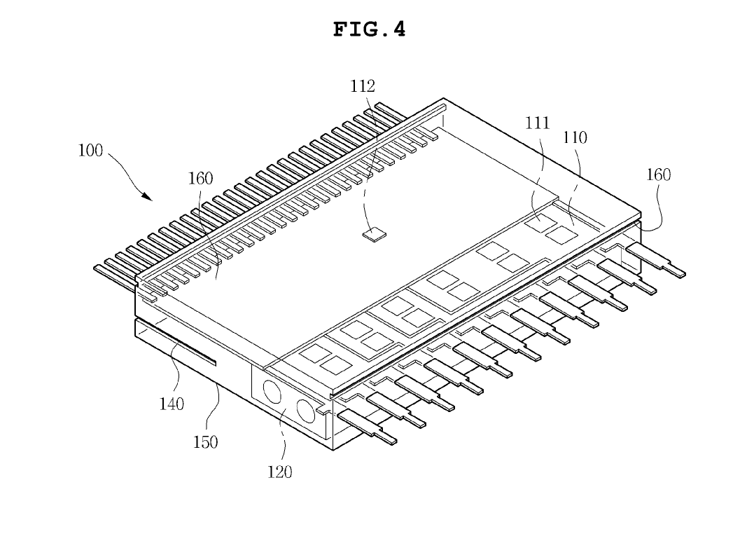

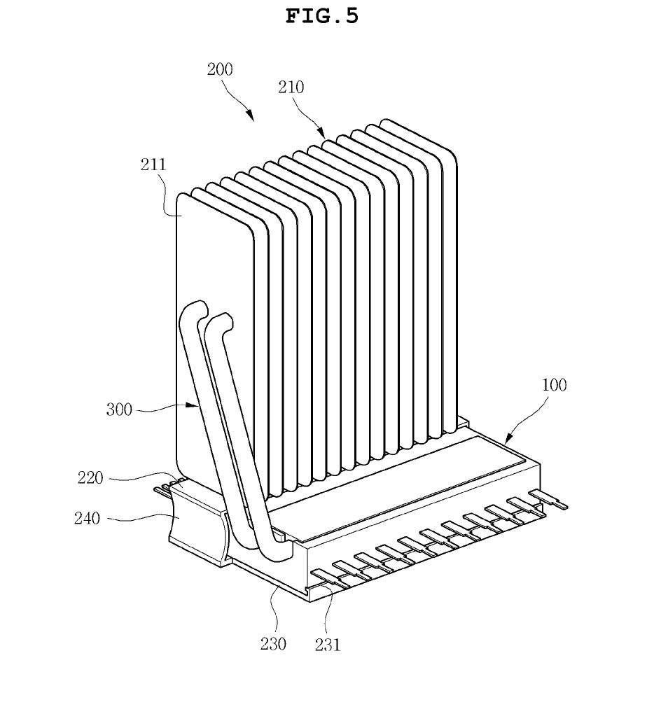

FIG. 3 is a perspective view showing a power package according to an embodiment of the present invention, and FIG. 4 is a perspective view showing a power package according to another embodiment of the present invention. As shown in FIGS. 3 and 4, the power package 100 is provided therein with a circuit substrate 110, on which is mounted a plurality of semiconductor chips that generate high heat. Preferably, the circuit substrate 110 is mounted with insulated gate bipolar transistors (IGBTs) 111 and a drive IC 112.

Further, in order to block the electromagnetic waves generated from the IGBTs 111 and the drive IC 112, an EMC region may be formed on the upper portion 150 of the power package 100.

Further, the circuit substrate 110 is provided at the lower portion thereof with a heat spread 120 in order to dissipate the high heat generated from the power package 100.

Further, the heat spread 120 may be provided with insert holes 121 having a diameter corresponding to the diameter of the second heat radiation member 300 in order to fix the second heat radiation member 300 which radiates the dissipated high heat.

Further, as shown in FIG. 4, the opposite side of the insert holes 121 of the heat spread 120 may be opened in order to allow the heat radiation module 200 to externally receive a coolant or allow the second heat radiation member 300 to extend outwards. Conversely, the opposite side thereof may be closed.

Further, the power package 100 may be provided with a guide groove 130 corresponding to the guide rail 231 of the lower contact plate 230 such that the power package 100 can slide along the contact plate assembly.

Further, the power package 100 may be provided with a fixing groove 140 corresponding to the stopper 221 of the upper contact plate 220 such that the stopper 221 is accepted into the fixing groove 140.

The first heat radiation member 210 of the power package module according to an embodiment of the present invention may be a heat sink including a plurality of radiation fins 211 provided in order to radiate the high heat generated from the power package 100.

Further, the radiation fins 211 of the first heat radiation member 210 may be provided with through-holes 212 having a diameter corresponding to the diameter of the second heat radiation member 300 such that the through-holes 212 connect the second heat radiation member 300 to the first heat radiation member 200.

As shown in FIGS. 2 and 3, the second heat radiation member 300 may be formed of L-shaped heat pipes having bending curvatures 311 and 321 such that one side 310 of the second heat radiation member 300 is connected to the first heat radiation member 210 through the through-holes 212, and the other side 320 thereof is connected to the power package 100 through the insert holes 121 formed in the heat spread 120.

In the present invention, the second heat radiation member includes a pair of heat pipes, but the number of heat pipes connected to the first heat radiation member 210 and the power package 100 is not limited.

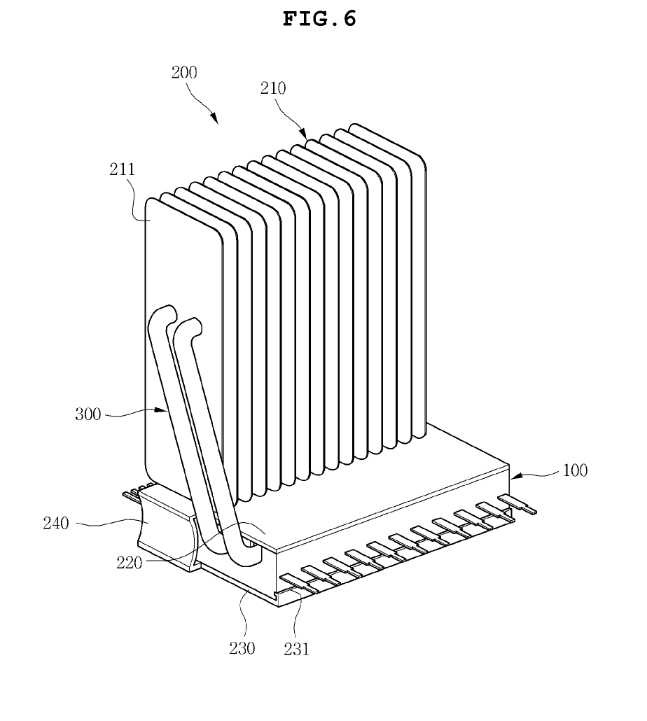

As shown in FIG. 5, one side 310 of the second heat radiation member 300 is connected to the first heat radiation member 210 through the through-holes 212 formed in the plurality of radiation fins 211 constituting the first heat radiation member 210, and the other side 320 thereof is connected to the power package 100 through the insert holes 121 formed in the heat spread 120.

Therefore, the high heat generated from the power package 100 is primarily dissipated by the heat spread 120, and is then secondarily transferred to the first heat radiation member 210 by the second heat radiation member 300 connected to the heat spread 120.

Then, the high heat transferred to the first heat radiation member 210 is finally discharged to the outside by the plurality of radiation fins 211 constituting the first heat radiation member 210.

Further, the high heat generated from the power package 100 can be dissipated to the underside of the power package module even by the heat spread which can be formed on the lower contact plate 230 of the contact panel assembly.

Thus, the power package module of the present invention is advantageous in that the high heat generated from the power package 100 can be rapidly dissipated and directed away from the upper and lower portions of the power package module to the outside using the heat radiation module 200, the second heat radiation member 300 and the heat spread (not shown) formed on the lower contact plate 230, thus improving the radiation performance of the power package module.

Further, since the coupling between the power package 100 and the heat radiation module 200 is as tight as possible, the volume of the power package module can be decreased, thus improving the radiation performance of the heat radiation module 200.

FIG. 6 is an assembled perspective view showing a power package module according to another embodiment of the present invention. As shown in FIG. 6, the upper contact plate 220 of the power package 100 may be extended such that it can cover the entire upper portion 150 of the power package 100.

Therefore, the area to which heat may be transferred from the heat spread of the power package 100 increases, thus further improving the radiation performance of the heat radiation module 200.

Further, the heat radiation module 200 and the power package 100 are strongly connected with each other using the upper contact plate extended to cover the entire upper portion 150 of the power package 100, thus improving the durability of the power package module.

As described above, according to the present invention, there is provided a power package module including a power package and a heat radiation module closely coupled with the power package as possible, thus improving the radiation performance of the heat radiation module.

Further, both upper and lower portions of a power package radiate heat, thus obtaining uniform radiation performance over the entire power package module.

Further, since a power package and a heat radiation module can be easily attached to and detached from each other, the manufacturing process can be simplified, the productivity of products can be increased, and defective products can be easily replaced even after the manufacturing process or the production of products has finished, when the power package or the heat radiation module is defective.

Further, a power package module including a power package and a heat radiation module closely coupled with the power package to the highest degree is provided, thus decreasing the volume of the power package module.

Furthermore, both upper and lower portions of a power package are radiated, thus solving the problem of the radiation performance of the power package module being deteriorated after the power package module has been used for a long period of time.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

Simple modifications, additions and substitutions of the present invention belong to the scope of the present invention, and the specific scope of the present invention will be clearly defined by the appended claims.

What is claimed is:

1. A power package module, comprising:
a power package mounted with a plurality of semiconductor chips;
a heat radiation module coming into contact with the power package and including a first heat radiation member for discharging heat generated from the power package; and
a second heat radiation member, one side of which is connected to the first heat radiation member and the other side of which is connected to the power package.

2. The power package module according to claim 1, wherein the heat radiation module further comprises a contact plate assembly disposed underneath the first heat radiation member and coming into contact with the power package.

3. The power package module according to claim 2, wherein the contact plate assembly comprises:
an upper contact plate coming into contact with an upper portion of the power package;
a lower contact plate coming into contact with a lower portion of the power package, in which the upper contact plate and the lower contact plate accommodate the power package therebetween; and
a plate connector connecting the upper contact plate to the lower contact plate and preventing the power package from becoming detached from the contact plate assembly.

4. The power package module according to claim 3, wherein the upper contact plate comprises a stopper disposed at one end thereof and fixing the power package to prevent the upper contact plate from becoming detached from the power package.

5. The power package module according to claim 3, wherein the lower contact plate comprises
a guide rail for slide-coupling the power package with the lower contact plate; and
a heat spread for dissipating heat generated from the power package.

6. The power package module according to claim 1, wherein the power package comprises:
a circuit substrate mounted with a plurality of insulated gate bipolar transistors (IGBTs) and a drive IC; and
a heat spread connected to a lower portion of the circuit substrate and dissipating the heat generated from the power package,
wherein the heat spread is provided with an insert hole having a diameter corresponding to a diameter of the second heat radiation member to connect the second heat radiation member to the power package through the insert hole.

7. The power package module according to claim 4, wherein the power package further comprises:
a fixing groove formed in a side of the power package corresponding to the stopper such that the stopper is accepted into the fixing groove.

8. The power package module according to claim 5, wherein the power package further comprises:
a guide groove formed in a side of the power package corresponding to a guide rail of the lower contact plate such that the power package slides along the guide rail.

9. The power package module according to claim 1, wherein the first heat radiation member is a heat sink including a plurality of radiation fins for discharging heat to the outside.

10. The power package module according to claim 9, wherein each of the plurality of radiation fins of the first heat radiation member is provided with a through-hole having a diameter corresponding to a diameter of the second heat radiation member such that the second heat radiation member is connected to the first heat radiation member by the through-hole.

11. The power package module according to claim 1, wherein the second heat radiation member is a [symbol] -shaped heat pipe having bent portions such that one side thereof is connected to the first heat radiation member by the through-hole, and the other side thereof is connected to the power package
